(19) United States
(12) Patent Application Publication
(10) Pub. No.: US 2013/0025666 A1
(43) Pub. Date: Jan. 31, 2013

(54) Novel Thin Film Solar Cell Structure

(71) Applicants: Sheng-Fu Horng, Hsinchu (TW); Ming-Kun Lee, Hsinchu (TW); Jen-Chun Wang, Hsinchu (TW); Yun-Ru Horng, Hsinchu (TW); Hsin-Fei Meng, Hsinchu (TW)

(72) Inventors: Sheng-Fu Horng, Hsinchu (TW); Ming-Kun Lee, Hsinchu (TW); Jen-Chun Wang, Hsinchu (TW); Yun-Ru Horng, Hsinchu (TW); Hsin-Fei Meng, Hsinchu (TW)

(73) Assignee: NATIONAL TSING HUA UNIVERSITY, Hsinchu (TW)

(21) Appl. No.: 13/542,475

(22) Filed: Jul. 5, 2012

(30) Foreign Application Priority Data
Jul. 27, 2011 (TW) 100126561

(51) Int. Cl. H01L 31/0224

(52) U.S. Cl. 136/256

(57) ABSTRACT

The present invention provides a kind of structure of a thin film solar cell, including: a transparent conductive layer, a first electrode, a second electrode, a conductive layer of metal, and a photoelectric conversion layer, wherein changing the structures of said first electrode and said second electrode can improve the efficiency of the cell. Because the distribution of electric potential is not uniform in the transparent conductive layer, it will reduce the efficiency of the cell. We can solve this problem by changing the electrode structures of the cell, and improve the efficiency of the cell.

### CROSS-REFERENCE TO RELATED APPLICATIONS

This Non-provisional application claims priority under 35 U.S.C. §119(a) on Patent Application No(s). 100126561 filed in Taiwan, Republic of China, Jul. 27, 2011, the entire contents of which are hereby incorporated by reference.

### FIELD OF THE INVENTION

This invention relates to a thin film solar cell structure, and more particularly, to a novel thin film solar cell structure with electrodes improvement for solving the problem of non-uniform potential distribution and then improving the efficiency of the solar cell.

### BACKGROUND OF THE INVENTION

The price of fossil fuel has skyrocketed due to the fossil fuel, as the main energy that mankind relied on over a long period of time, probably exhausted during 21 centuries. Therefore, alternative energies, such as solar energy, wind power and hydraulic power, are continuously developed from each country of the world. In the presence of all, solar energy, which is a cleaner alternative energy without generating greenhouse effect, has become a popular energy for applying to many industrial circles, such as aviation, industry, and meteorological phenomena fields, etc. Thus, how to apply the solar cell technology to daily life for resolving energy shortage and environment pollution has become a field that many governments and factories of the world devote efforts to researching.

The materials of solar cell technology are developed from mono crystalline silicon (first generation) to polycrystalline silicon, amorphous silicon and III-V compound (second generation), such as CdTe, GaAs and InGaAs. Polycrystalline silicon is made of different mono crystalline silicon. With comparing to mono crystalline silicon and amorphous silicon, polycrystalline silicon is more difficult in cutting and processing operation, and the efficiency of polycrystalline silicon solar cell is lower than mono crystalline silicon solar cell. So that polycrystalline silicon solar cell is adopted for use in low power electrical application systems. Besides, the photoelectric conversion efficiency of solar cells with amorphous silicon thin film can not be effective raised due to the amorphous silicon thin film hardly to transfer the electron-hole to electrodes effectively and the wavelength absorbing region being narrower. Nowadays, shapes of most solar cells are designed to be rectangular solid. With reference to FIG. 1, this illustrates a schematic of a traditional solar cell element.

The main purpose for researching and developing solar cell technologies is to improve the photoelectric conversion efficiency of solar cells. For example, the surfaces of solar cells fabricated to be pyramid shape structures, adding anti-reflective layer for decreasing the light reflecting rate and doping other materials into conducting layer for decreasing the current impedance are popular ways for improving photoelectric conversion efficiency of solar cells. However, these ways aforementioned are mostly to improve the materials or manufacturing processes of solar cells for raising the photoelectric conversion efficiency. In which, due to the demand of high transmission rate of the transparent layer, the original material, such as metal, of the transparent layer is replaced by conductive glass. Thus, a problem of low lateral electric conductivity of the transparent layer is caused. When the solar cells absorbs light for generating current, the low lateral electric conductivity leads these large area solar cells to have a non-uniform distribution of electric potential in the transparent layer. The non-uniform distribution of electric potential decreases the efficiency of the whole solar cells. Traditional technologies improve materials of the transparent layer of solar cells for increasing the intensity of incident light and for increasing efficiency of the solar cells. However, the problem of non-uniform distribution of electric potential of the solar cells is remained.

It is desirable and important, therefore, to provide solar cells with high photovoltaic conversion efficiency without increasing manufacturing process complexity and replacing or adding new materials.

### BRIEF SUMMARY OF THE INVENTION

The invention provides a novel thin film solar cell structure, including: a transparent conductive layer having a first terminal and a second terminal; a first electrode disposed on the first terminal of the transparent conductive layer; a second electrode disposed on the second terminal of the transparent conductive layer; a metal conductive layer disposed opposite to the transparent conductive layer and having the same shape with the transparent conductive layer; and a photoelectric conversion layer disposed between the metal conductive layer and the transparent conductive layer for converting absorbed solar radiation into electrical energy; wherein both the first electrode and the first terminal of the transparent conductive layer possess a first “ [symbol] ” shape structure and the first “ [symbol] ” shape structure includes a first bending angle; wherein both the second electrode and the second terminal of the transparent conductive layer possess a second “ [symbol] ” shape structure and the second “ [symbol] ” shape structure includes a second bending angle.

According to one exemplary embodiment of the present invention abovementioned, the first bending angle equals to the second bending angle.

According to one exemplary embodiment of the present invention abovementioned, the first bending angle has an angle magnitude range from 1 to 179 degrees.

According to one exemplary embodiment of the present invention abovementioned, the second bending angle has an angle magnitude range from 1 to 179 degrees.

According to one exemplary embodiment of the present invention abovementioned, the transparent conductive layer is a transparent conductive glass made from indium tin oxide (ITO).

According to one exemplary embodiment of the present invention abovementioned, the metal conductive layer is selected from the metal group consisting of aluminum, gold, silver, titanium and nickel.

According to one exemplary embodiment of the present invention abovementioned, the photoelectric conversion layer is an amorphous silicon thin film layer or a microcrystalline silicon thin film layer.

The efficiency of solar cells can be improved by changing shape structures of the first electrode and the second electrode. After changing electrode shape structure of the solar cell for solving the problem of low efficiency of the solar cell caused by non-uniform potential distribution in the transparent conductive layer, the efficiency of the solar cell is, therefore, improved.

The details and technology of the present invention are described below with reference to the accompanying drawings:

### BRIEF DESCRIPTION OF THE DRAWINGS

FIG. 1 illustrates a schematic diagram of traditional solar cell elements.

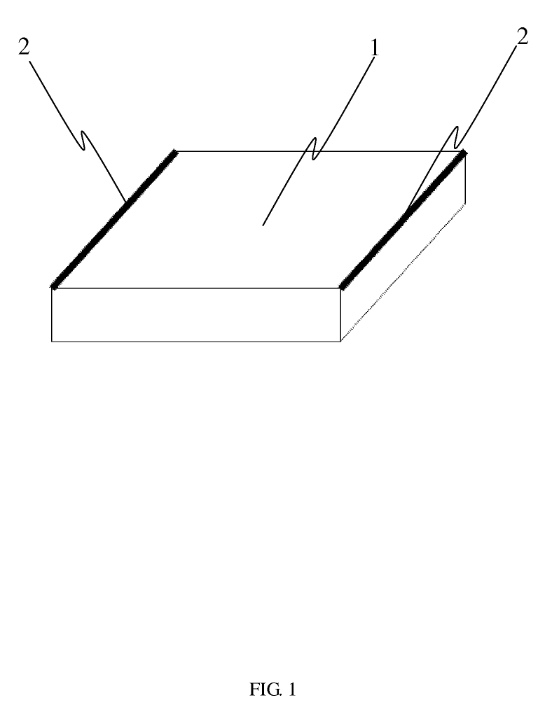

FIG. 2 illustrates a schematic diagram of the thin film solar cell structure of the present invention.

FIG. 3 illustrates a current density-voltage relationship diagram measured after the solar cell with various electrode angles absorbing light of the present invention.

### DETAILED DESCRIPTION OF THE INVENTION

The objects, spirits, and advantages of the preferred embodiments ┌a novel thin film solar cell structure┘ of the present invention will be readily understood by the accompanying detailed descriptions. For clarity of disclosure, and not by way of limitation, the detailed description of the invention is divided into the subsections that follow.

The present invention provides a solar cell structure for improving efficiency. Moreover, the structure is compatible to the manufacturing process of the original solar cell without changing materials or tuning manufacturing process complexly. Furthermore, the efficiency of the solar cell is effectively improved without increasing the difficulty of manufacturing process integration.

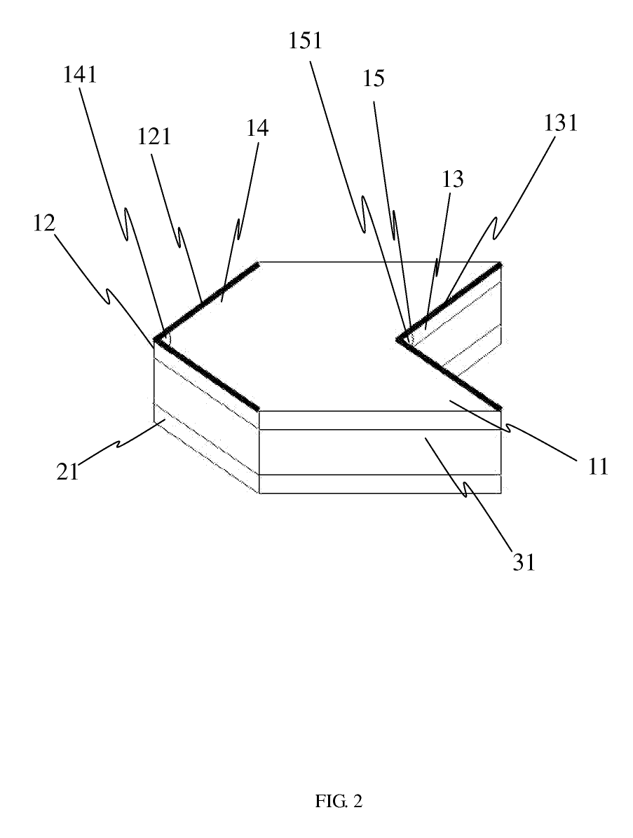

FIG. 2 illustrates a schematic diagram of the thin film solar cell structure of the present invention. As shown, the thin film solar cell structure includes a transparent conductive layer 11, a first electrode 121, a second electrode 131, a metal conductive layer 21 and a photoelectric conversion layer 31.

The transparent conductive layer 11 has a first terminal 12 and a second terminal 13, and the transparent conductive layer 11 is a transparent conductive glass made from metal oxides, such as indium tin oxide (ITO), or electrical conductive polymer. The first electrode 121 is disposed on the first terminal 12 of the transparent conductive layer 11, and the second electrode 131 is disposed on the second terminal 13 of the transparent conductive layer 11. In which, both the first electrode 121 and the first terminal 12 of the transparent conductive layer 11 possess a first “ [symbol] ” shape structure 14 and the first “ [symbol] ” shape structure 14 includes a first bending angle 141. Meanwhile, both the second electrode 131 and the second terminal 13 of the transparent conductive layer 11 possess a second “ [symbol] ” shape structure 15 and the second “ [symbol] ” shape structure 15 includes a second bending angle 151. For operating the solar cell with higher photoelectric conversion efficiency, high transmission rate of the transparent conductive layer 11 is demanded. Therefore, the original material, such as metal, of the transparent conductive layer 11 is replaced by conductive glass and a problem of low lateral electric conductivity of the transparent conductive layer 11 is caused. When the solar cell absorbs light for generating current, the low lateral electric conductivity leads the large area solar cell with a non-uniform distribution of electric potential in the transparent conductive layer 11. The non-uniform distribution of electric potential decreases the total efficiency of the solar cell. Due to metal possesses a higher electric conductivity, the problem of non-uniform distribution of electric potential in the transparent conductive layer (conductive glass) 11 is improved after burying metal electrodes (the first electrode 121 and the second electrode 131) with various shapes in the transparent conductive layer 11. Also, the problem of non-uniform distribution of electric potential is solved through burying metal electrodes in the transparent conductive layer 11 and the efficiency of the solar cell is, therefore, improved.

The metal conductive layer 21 is disposed opposite to the transparent conductive layer 11 and has the same shape with the transparent conductive layer 11. Therefore, two terminals of the metal conductive layer 21 corresponding to two terminals of the transparent conductive layer 11 possess two corresponding “ [symbol] ” shape structures. Moreover, the metal conductive layer 21 is selected from the metal group consisting of aluminum, gold, silver, titanium and nickel and is selected from the manufacturing process consisting of evaporation process and sputtering process.

The photoelectric conversion layer 31 is disposed between the metal conductive layer 21 and the transparent conductive layer 11. Thus, the photoelectric conversion layer 31 possesses two “ [symbol] ” shape structures in responsive to the metal conductive layer 21 and the transparent conductive layer 11. The photoelectric conversion layer 31 converts the absorbed solar radiation into electrical energy and the photoelectric conversion layer 31 is an amorphous silicon thin film layer or a microcrystalline silicon thin film layer.

The first bending angle 141 of the first “ [symbol] ” shape structure 14 on the first terminal 12 of the transparent conductive layer 11 equals to the second bending angle 15 of the second “ [symbol] ” shape structure 15 on the second terminal 13. While the first bending angle 141 is an acute angle with angles less than 90 degrees, the solar cell possesses a better photoelectric converting efficiency. In one embodiment of the present invention, the solar cell possesses the best photoelectric converting efficiency while the first bending angle 141 is 54 degrees, but not by way of limitation. It is an example, but not limited, for describing that the first bending angle 141 is an acute angle with angles less than 90 degrees in the embodiment. The first bending angle 141 can be an obtuse angle with angles larger than 90 degrees or a right angle with angles equal to 90 degrees. Therefore, each of the first bending angle 141 and the second bending angle 151 has an angle magnitude range from 1 to 179 degrees, or 45 to 120 degrees. The angle magnitude range of the first bending angle 141 and the second bending angle 151 is not limited in the present invention.

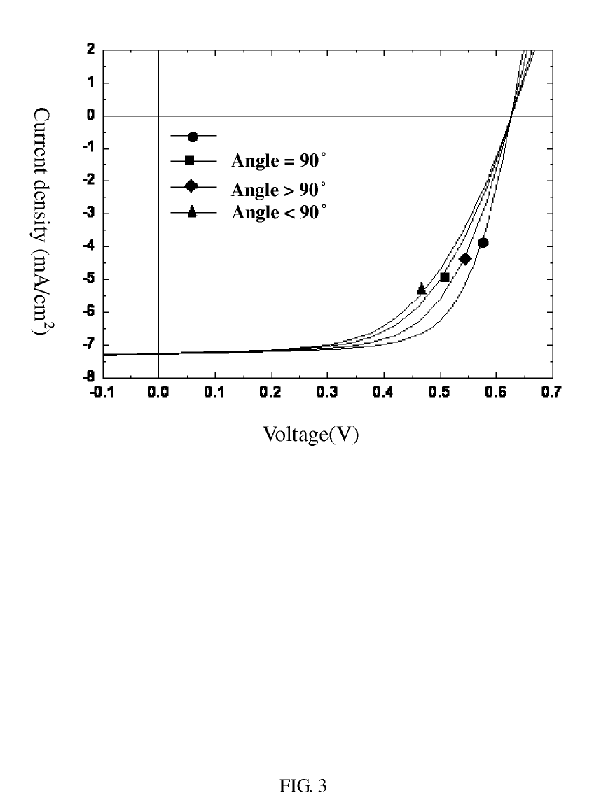

FIG. 3 illustrates a current density-voltage relationship diagram measured after the solar cell with various “ [symbol] ” shape angles of the electrodes (the first electrode 121 and the second electrode 131) absorbing light of the present invention. From FIG. 3, we can see that the less the bending angles of the first electrode 121 and the second electrode 131 are, the better the photoelectric converting efficiency is.

Table 1 shows data, such as current density, open circuit voltage, filling factor, energy converting efficiency, average maximum efficiency point and standard maximum efficiency point, measured from the solar cell when the solar cell absorbs light after changing shape structures of the solar cell and adding various “ [symbol] ” shape electrodes with various angle shapes. From the data in Table 1, it is obviously that the solar cell has maximum energy converting efficiency, 2.9%, when the first bending angle is less than 90 degrees.

TABLE 1
Data measured from the solar cell during the solar cell absorbing light and
adding electrodes with various angle shapes.

| | Angle = 180° | Angle = 90° | Angle <90° | Angle >90° |
|---|---|---|---|---|
| Current | −7.24 | −7.25 | 7.26 | 7.24 |
| density | | | | |
| (mA/cm²) | | | | |
| Open circuit | 0.63 | 0.63 | 0.63 | 0.63 |
| voltage (V) | | | | |
| Filling factor | 56.6 | 59.2 | 63.8 | 57.3 |
| Energy | 2.57 | 2.69 | 2.90 | 2.60 |
| converting | | | | |
| efficiency | | | | |
| (%) | | | | |
| Average | 0.50 | 0.48 | 0.45 | 0.49 |
| (maximum | | | | |
| efficiency | | | | |
| point) | | | | |
| Standard | 0.036 | 0.033 | 0.023 | 0.037 |
| (maximum | | | | |
| efficiency | | | | |
| point) | | | | |

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims.

What is claimed is:

1. A novel thin film solar cell structure, including:
a transparent conductive layer having a first terminal and a second terminal;
a first electrode disposed on the first terminal of the transparent conductive layer;
a second electrode disposed on the second terminal of the transparent conductive layer;
a metal conductive layer disposed opposite to the transparent conductive layer and having the same shape with the transparent conductive layer; and
a photoelectric conversion layer disposed between the metal conductive layer and the transparent conductive layer for converting absorbed solar radiation into electrical energy;
wherein both the first electrode and the first terminal of the transparent conductive layer possess a first “ [symbol] ” shape structure and the first “ [symbol] ” shape structure includes a first bending angle;
wherein both the second electrode and the second terminal of the transparent conductive layer possess a second “ [symbol] ” shape structure and the second “ [symbol] ” shape structure includes a second bending angle.

2. The novel thin film solar cell structure according to claim 1, wherein the first bending angle equals to the second bending angle.

3. The novel thin film solar cell structure according to claim 1, wherein the first bending angle has an angle magnitude range from 45 to 120 degrees.

4. The novel thin film solar cell structure according to claim 1, wherein the second bending angle has an angle magnitude range from 45 to 120 degrees.

5. The novel thin film solar cell structure according to claim 1, wherein the transparent conductive layer is made from metal oxides or electrically conductive polymer.

6. The novel thin film solar cell structure according to claim 1, wherein the photoelectric conversion layer is an amorphous silicon thin film layer or a microcrystalline silicon thin film layer.
